(19) United States
(12) Patent Application Publication
(10) Pub. No.: US 2026/0130120 A1
(43) Pub. Date: May 7, 2026

(54) MRAM AND FABRICATING METHOD OF THE SAME

(71) Applicant: UNITED MICROELECTRONICS CORP., Hsin-Chu City (TW)

(72) Inventors: Yi-Ching Wang, Taichung City (TW); Chia-Fu Cheng, Taipei City (TW); Tzu-Hung Yang, Tainan City (TW); Wei Chen, Tainan City (TW); Chun-Yao Yang, Kaohsiung City (TW)

(73) Assignee: UNITED MICROELECTRONICS CORP., Hsin-Chu City (TW)

(21) Appl. No.: 18/991,728

(22) Filed: Dec. 23, 2024

(30) Foreign Application Priority Data
Nov. 5, 2024 (TW) 113142299

(51) Int. Cl. H10N 50/85; H10B 61/00; H10N 50/10

(52) U.S. Cl. CPC H10N 50/85; H10B 61/10; H10N 50/10

(57) ABSTRACT

An MRAM includes a bottom electrode, a magnetic tunnel junction, a cap layer and a top electrode stacked in sequence from bottom to top. The magnetic tunnel junction includes a free layer. The cap layer includes a mixture layer. The mixture layer includes a magnesium layer, a magnesium oxide layer, a tantalum oxide layer and a first tantalum layer. The mixture layer contacts the free layer.

### BACKGROUND OF THE INVENTION

### 1. Field of the Invention

The present invention relates to a magnetoresistive random access memory (MRAM), and a fabricating method of the same, and more particularly to an MRAM having high tunnel magnetoresistance (TMR) and coercivity, and a fabricating method of the same.

### 2. Description of the Prior Art

Many modern electronic devices contain electronic memory configured to store data. Electronic memory may be volatile memory or non-volatile memory. Volatile memory stores data only while it is powered, while non-volatile memory is able to store data even when power is off. In addition, process shrinkage is an important trend in advanced semiconductor manufacturing processes. Under this trend, because magnetoresistive random access memory (MRAM) has high read and write speeds, low power consumption, and can store data even when power is off, the MRAM is particularly suitable for the embedded system. Since MRAM has superior advantages than other electronic memories, its potential in the next generation of non-volatile memory technology is expected.

MRAM does not use electrons to store bit information, but uses magnetic polarization to store data. During a write mode, the magnetic material can be switched between two opposite magnetic states through an external magnetic field to store data.

However, conventional MRAM still needs to be improved. For example, increasing the magnetic moment switch speed, the tunnel magnetoresistance (TMR) and coercivity of MRAM to raise the operating performance of MRAM is an object of the semiconductor industry.

### SUMMARY OF THE INVENTION

In view of this, the present invention provides an MRAM with special components in a cap layer to increase the magnetic moment switch speed, tunnel magnetoresistance and coercivity of the MRAM.

According to a preferred embodiment of the present invention, an MRAM includes a bottom electrode, a magnetic tunnel junction, a cap layer and a top electrode stacked in sequence from bottom to top. The magnetic tunnel junction includes a free layer. The cap layer includes a mixture layer. The mixture layer includes a magnesium layer, a magnesium oxide layer, a tantalum oxide layer and a first tantalum layer, and the mixture layer contacts the free layer.

A fabricating method of an MRAM includes forming a bottom electrode, a magnetic tunnel junction, a cap layer and a top electrode stacked in sequence from bottom to top. The magnetic tunnel junction includes a free layer. Fabricating steps of the cap layer include depositing a magnesium layer. Next, oxygen gas is provided and the magnesium layer is heated to make the oxygen gas react with part of the magnesium layer to form a magnesium oxide layer. After the magnesium oxide layer is formed, a first tantalum layer is deposited to cover the magnesium layer and the magnesium oxide layer to make some of oxygen atoms in the magnesium oxide layer diffuse into the first tantalum layer to form a tantalum oxide layer.

A fabricating method of an MRAM includes forming a bottom electrode, a magnetic tunnel junction, a cap layer and a top electrode stacked in sequence from bottom to top. The magnetic tunnel junction includes a free layer. Fabricating steps of the cap layer include depositing a magnesium layer and a first tantalum layer in a listed sequence. Then, oxygen gas is provided and the magnesium layer and the first tantalum layer are heated to make oxygen react with part of the magnesium layer and part of the first tantalum layer to form a magnesium oxide layer and a tantalum oxide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 depict a fabricating method of an MRAM according to a preferred embodiment of the present invention, wherein:

FIG. 2 depicts fabricating steps in continuous of FIG. 1

FIG. 3 to FIG. 5 depict a fabricating method of a cap layer according to a first preferred embodiment of the present invention, wherein:

FIG. 4 depicts fabricating steps in continuous of FIG. 3; and

FIG. 5 depicts fabricating steps in continuous of FIG. 4.

FIG. 6 to FIG. 8 depict a fabricating method of a cap layer according to a second preferred embodiment of the present invention, wherein:

FIG. 7 depicts fabricating steps in continuous of FIG. 6; and

FIG. 8 depicts fabricating steps in continuous of FIG. 7.

FIG. 9 is a concentration distribution chart of magnesium atoms, oxygen atoms and tantalum atoms in the mixture layer according to the first preferred embodiment of the present invention.

FIG. 10 is a concentration distribution chart of magnesium atoms, oxygen atoms and tantalum atoms in the mixture layer according to the second preferred embodiment of the present invention.

### DETAILED DESCRIPTION

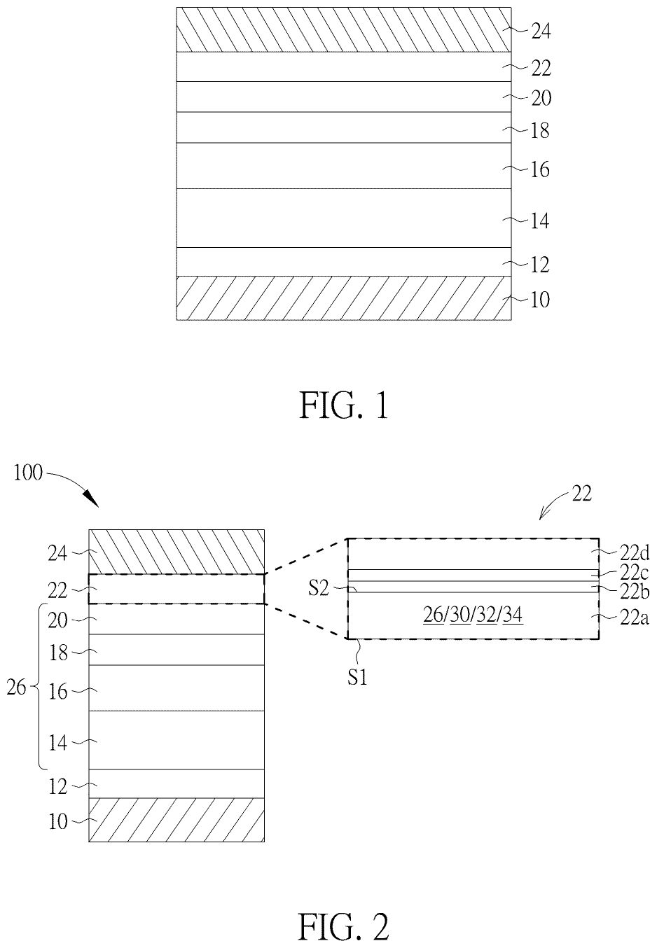

FIG. 1 to FIG. 2 depict a fabricating method of an MRAM according to a preferred embodiment of the present invention.

As shown in FIG. 1, a bottom electrode 10, a seed layer 12, a pinned layer 14, a reference layer 16, an oxide layer 18, a free layer 20, a cap layer 22 and a top electrode 24 are formed in sequence. The bottom electrode 10, the seed layer 12, the pinned layer 14, the reference layer 16, the oxide layer 18, the free layer 20 and the top electrode 24 are preferably formed by physical vapor deposition, such as sputtering. The fabricating method of the cap layer 22 will be described in detail in the following description. As shown in FIG. 2, the top electrode 24, the cap layer 22, the free layer 20, the oxide layer 18, the reference layer 16, the pinned layer 14, the seed layer 12 and the bottom electrode 10 are patterned. Then, the top electrode 24, the cap layer 22, the free layer 20, the oxide layer 18, the reference layer 16, the pinned layer 14, the seed layer 12 and the bottom electrode 10 which are patterned are heated along with the back end of line processes. In this way, an MRAM 100 of the present invention is formed.

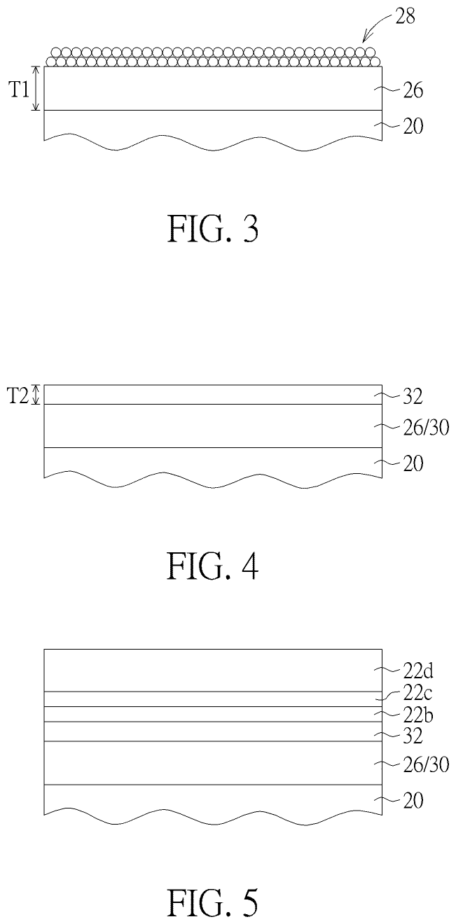

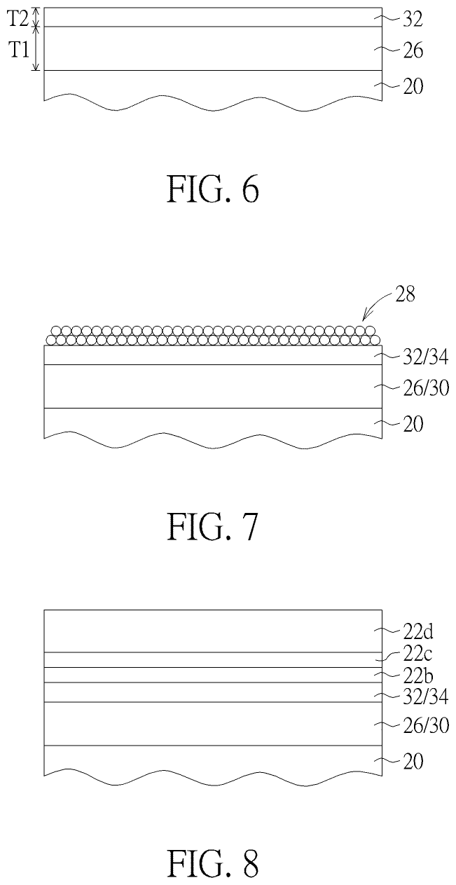

The fabricating method of the cap layer 22 of the present invention includes the methods provided by a first preferred embodiment and a second preferred embodiment. FIG. 3 to FIG. 5 depict a fabricating method of a cap layer according to a first preferred embodiment of the present invention. FIG. 6 to FIG. 8 depict a fabricating method of a cap layer according to a second preferred embodiment of the present invention. In the description of the first preferred embodiment and the second preferred embodiment, elements which are substantially the same as those in FIG. 1 and FIG. 2 are denoted by the same reference numerals; an accompanying explanation is therefore omitted.

As shown in FIG. 3 and FIG. 4, according to the first preferred embodiment of the present invention, after the free layer 20 is formed, a magnesium layer 26 is formed to cover the free layer 20 by using physical vapor deposition. At this time, the magnesium layer 26 which has not reacted with oxygen atoms has a first thickness T1. Then, oxygen gas 28 is provided and the magnesium layer 26 is heated together with oxygen gas 28 to make oxygen atoms of oxygen gas 28 react with part of the magnesium layer 26 to form a magnesium oxide layer 30. After forming the magnesium oxide layer 30, a first tantalum layer 32 is formed by using physical vapor deposition and the first tantalum layer 32 covers the magnesium layer 26 and the magnesium oxide layer 30. At this time, the first tantalum layer 32 which has not reacted with oxygen atoms has a second thickness T2. The first thickness T1 is greater than the second thickness T2. Advantageously, the first thickness T1 is 3 times the second thickness T2. After that, as shown in FIG. 5, a first metal layer 22b, a second metal layer 22c and a third metal layer 22d are sequentially formed to be stacked on the first tantalum layer 32 from bottom to top by using physical vapor deposition. The first metal layer 22b is preferably ruthenium, the second metal layer 22c is preferably tantalum, and the third metal layer 22d is preferably ruthenium. At this time, the first tantalum layer 32, the magnesium layer 26, the magnesium oxide layer 30, the first metal layer 22b, the second metal layer 22c and the third metal layer 22d are together defined as the cap layer 22. Next, as shown in FIG. 1, the top electrode 24 is formed to cover and contact the third metal layer 22d in the cap layer 22. Then, as shown in the steps of FIG. 2, the top electrode 24, the cap layer 22, the free layer 20, the oxide layer 18, the reference layer 16, the pinned layer 14, the seed layer 12 and the bottom electrode 10 are patterned. After that, during back end of line processes, the top electrode 24, the cap layer 22, the free layer 20, the oxide layer 18, the reference layer 16, the pinned layer 14, the seed layer 12 and the bottom electrode 10 are heated, and some oxygen atoms in the magnesium oxide layer 30 diffuse into the first tantalum layer 32 to make the first tantalum layer 32 to react with oxygen atoms to form a tantalum oxide layer 34. In this way, the magnesium layer 26, the magnesium oxide layer 30, the tantalum oxide layer 34 and the first tantalum layer 32 together form the mixture layer 22a. In the mixture layer 22a, the magnesium layer 26, the magnesium oxide layer 30, the tantalum oxide layer 34 and the first tantalum layer 32 have no obvious delamination. That is, in each region of the mixture layer 22a, the magnesium layer 26, the magnesium oxide layer 30, the tantalum oxide layer 34 and the first tantalum layer 32 are mixed together. At this time, the cap layer 22 is formed by the third metal layer 22d, the second metal layer 22c, the first metal layer 22b and the mixture layer 22a. Now, the top electrode 24, the cap layer 22 (with the mixture layer 22a), the free layer 20, the oxide layer 18, the reference layer 16, the pinned layer 14, the seed layer 12 and the bottom electrode 10 together form the MRAM 100 of the present invention.

As shown in FIG. 6, according to the second preferred embodiment, after forming the free layer 20, a magnesium layer 26 and a first tantalum layer 32 are sequentially formed by using physical vapor deposition. At this time, the first magnesium layer 26 has a first thickness T1, and the first tantalum layer 32 has a second thickness T2. The first thickness T1 is greater than the second thickness T2. Preferably, the first thickness T1 is 3 times the second thickness T2. As shown in FIG. 7, oxygen gas 28 is provided and the magnesium layer 26 and the first tantalum layer 32 are heated together with the oxygen gas 28 to make oxygen gas 28 react with part of the magnesium layer 26 and part of the first tantalum layer 32 to form a magnesium oxide layer 30 and a tantalum oxide layer 34. Later, as shown in FIG. 8, a first metal layer 22b, a second metal layer 22c and a third metal layer 22d are sequentially formed to be stacked on the first tantalum layer 32 from bottom to top by using physical vapor deposition. The first metal layer 22b is preferably ruthenium, the second metal layer 22c is preferably tantalum, and the third metal layer 22d is preferably ruthenium. At this time, the magnesium layer 26, the magnesium oxide layer 30, the first tantalum layer 32, the tantalum oxide layer 34, the first metal layer 22b, the second metal layer 22c and the third metal layer 22d are together to be defined as the cap layer 22. Then, as shown in the steps in FIG. 1, the top electrode 24 is formed to cover the cap layer 22. Next, as shown in the steps of FIG. 2, the top electrode 24, the cap layer 22, the free layer 20, the oxide layer 18, the reference layer 16, the pinned layer 14, the seed layer 12 and the bottom electrode 10 are patterned. After that, during back end of line processes, the top electrode 24, the cap layer 22, the free layer 20, the oxide layer 18, the reference layer 16, the pinned layer 14, the seed layer 12 and the bottom electrode 10 are heated. Heating allows the magnesium layer 26, the magnesium oxide layer 30, the tantalum oxide layer 34 and the first tantalum layer 32 to mix better. Now, the magnesium layer 26, the magnesium oxide layer 30, the tantalum oxide layer 34 and the first tantalum layer 32 together form a mixture layer 22a. The cap layer 22 is formed by the third metal layer 22d, the second metal layer 22c, the first metal layer 22b and the mixture layer 22a. Now, the top electrode 24, the cap layer 22 (with the mixture layer 22a), the free layer 20, the oxide layer 18, the reference layer 16, the pinned layer 14, the seed layer 12 and the bottom electrode 10 together form the MRAM 100 of the present invention.

As shown in FIG. 2, an MRAM 100 includes a bottom electrode 10, a seed layer 12, a magnetic tunnel junction 26, a cap layer 22 and a top electrode 24 are stacked in sequence from bottom to top. The magnetic tunnel junction 26 includes a pinned layer 14, a reference layer 16, an oxide layer 18 and a free layer 20 stacked from bottom to top. The oxide layer 18 contacts the free layer 20 and the reference layer 16. The cap layer 22 includes a mixture layer 22a, a first metal layer 22b, a second metal layer 22c and a third metal layer 22d sequentially stacked from bottom to top. The mixture layer 22a includes a magnesium layer 26, a magnesium oxide layer 30, a tantalum oxide layer 34 and a first tantalum layer 32. In each region of the mixture layer 22a, the magnesium layer 26, the magnesium oxide layer 30, the tantalum oxide layer 34 and the first tantalum layer 32 are mixed together. The mixture layer 22a contacts the free layer 20 and the first metal layer 22b. According to a preferred embodiment of the present invention, the first metal layer 22b, the second metal layer 22c and the third metal layer 22d respectively include Ru, Ta, V, Mn, Zn, Mo, W, Re or Os.

The pinned layer 14 includes PtMn, IrMn or PtIr. The reference layer 16 and the free layer 20 respectively include Fe, Co, Ni, FeNi, FeCo, CoNi, FeB, FePt, FePd or CoFeB. The oxide layer 18 includes MgO, Al₂O₃, NiO, GdO, Ta₂O₅, MoO₂, TiO₂ or WO₂. The top electrode 24 and the bottom electrode 10 respectively include Ti, Ta, TiN, TaN, W, Cu or Al.

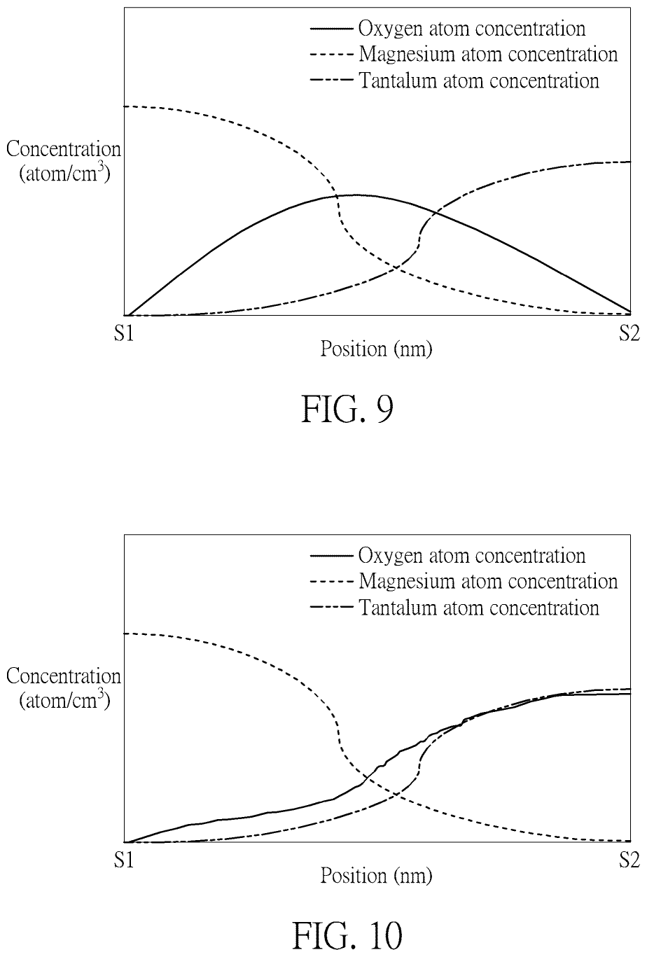

FIG. 9 is a concentration distribution chart of magnesium atoms, oxygen atoms and tantalum atoms in the mixture layer according to the first preferred embodiment of the present invention. FIG. 10 is a concentration distribution chart of magnesium atoms, oxygen atoms and tantalum atoms in the mixture layer according to the second preferred embodiment of the present invention.

As shown in FIG. 2, the mixture layer 22a includes a bottom surface S1 and a top surface S2. The bottom surface S1 contacts the free layer 20. The top surface S2 contacts the first metal layer 22b. The top surface S2 is closer to the top electrode 24 than the bottom surface S1. The top surface S2 is opposite to the bottom surface S1. As shown in FIG. 9, the mixture layer 22a which is formed by using the steps provided in the first preferred embodiment includes an oxygen atom concentration, a magnesium atom concentration and a tantalum atom concentration. The oxygen atom concentration continuously decreases from the middle of the mixture layer 22a respectively toward the top surface S2 and the bottom surface S1. The concentration of magnesium atoms decreases from the bottom surface S1 to the top surface S2. The concentration of tantalum atoms increases from the bottom surface S1 to the top surface S2.

On the other hand, as shown in FIG. 10, the mixture layer 22a which is formed by using the steps provided in the second preferred embodiment includes an oxygen atom concentration, a magnesium atom concentration and a tantalum atom concentration. The oxygen atom concentration increases continuously from the bottom surface S1 to the top surface S2. That is, the oxygen atom concentration continuously increases from the bottom surface S1 toward the top electrode 24. The magnesium atom concentration decreases from the bottom surface S1 toward the top surface S2. The tantalum atom concentration increases from the bottom surface S1 toward the top surface S2

The cap layer of the MRAM of the present invention includes a magnesium layer, a magnesium oxide layer, a tantalum oxide layer and a first tantalum layer. The magnesium oxide layer and the tantalum oxide layer can help improve the perpendicular magnetic anisotropy (PMA) of the MRAM. The first tantalum layer absorbs boron atoms from the free layer to increase the coercivity of the free layer to resist interference from magnetic fields or electric fields from environment. The magnesium layer protects the surface of the free layer and helps reduce the damping constant. In this way, the speed of magnetic moment switch of the free layer can be increased. Moreover, the tunnel magnetoresistance and coercivity of the MRAM fabricated by using the method of the second preferred embodiment has a better performance than the MRAM fabricated by using the method of the first preferred embodiment. However, both the MRAMs formed by using the methods of the first preferred embodiment and the second preferred embodiment have higher tunnel magnetoresistance and greater coercivity than the conventional MRAMs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A magnetoresistive random access memory (MRAM), comprising:
a bottom electrode, a magnetic tunnel junction, a cap layer and a top electrode stacked in sequence from bottom to top, wherein the magnetic tunnel junction comprises a free layer, and wherein the cap layer comprises a mixture layer, the mixture layer comprises a magnesium layer, a magnesium oxide layer, a tantalum oxide layer and a first tantalum layer, and the mixture layer contacts the free layer.

2. The MRAM of claim 1, wherein the mixture layer comprises a top surface and a bottom surface, and the top surface and the bottom surface are opposite to each other, the bottom surface contacts the free layer, and the top surface is closer to the top electrode than the bottom surface, the mixture layer has an oxygen atom concentration, the oxygen atom concentration decreases continuously from a middle of the mixture layer respectively toward the top surface and the bottom surface.

3. The MRAM of claim 1, wherein the mixture layer comprises a bottom surface, the bottom surface contacts the free layer, the mixture layer has an oxygen atom concentration, the oxygen atom concentration increases continuously from the bottom surface toward the top electrode.

4. The MRAM of claim 1, wherein the magnetic tunnel junction further comprising: a pinned layer, a reference layer and an oxide layer stacked from bottom to top, and the oxide layer contacts the free layer.

5. The MRAM of claim 4, wherein the pinned layer comprises PtMn, IrMn or PtIr, the reference layer and the free layer respectively comprise Fe, Co, Ni, FeNi, FeCo, CoNi, FeB, FePt, FePd or CoFeB, and the oxide layer comprises MgO, Al₂O₃, NiO, GdO, Ta₂O₅, MoO₂, TiO₂ or WO₂.

6. The MRAM of claim 1, wherein the top electrode and the bottom electrode respectively comprise Ti, Ta, TiN, TaN, W, Cu or Al, the cap layer further comprises a first metal layer, a second metal layer and a third metal layer sequentially stacked from bottom to top on the mixture layer, the first metal layer, the second metal layer and the third metal layer respectively comprise Ru, Ta, V, Mn, Zn, Mo, W, Re or Os.

7. A fabricating method of a magnetoresistive random access memory (MRAM), comprising:
forming a bottom electrode, a magnetic tunnel junction, a cap layer and a top electrode stacked in sequence from bottom to top, wherein the magnetic tunnel junction comprises a free layer, and fabricating steps of the cap layer comprise:
depositing a magnesium layer;
providing oxygen gas and heating the magnesium layer to make the oxygen gas react with part of the magnesium layer to form a magnesium oxide layer; and
after forming the magnesium oxide layer, depositing a first tantalum layer to cover the magnesium layer and the magnesium oxide layer to make some of oxygen atoms in the magnesium oxide layer diffuse into the first tantalum layer to form a tantalum oxide layer.

8. The fabricating method of a MRAM of claim 7, wherein the magnesium layer, the magnesium oxide layer, the tantalum oxide layer and the first tantalum layer form a mixture layer, and the mixture layer contacts the free layer.

9. The fabricating method of a MRAM of claim 8, wherein the mixture layer comprises a top surface and a bottom surface, and the top surface and the bottom surface are opposite to each other, the bottom surface contacts the free layer, and the top surface is closer to the top electrode than the bottom surface, the mixture layer has an oxygen atom concentration, the oxygen atom concentration decreases continuously from a middle of the mixture layer respectively toward the top surface and the bottom surface.

10. The fabricating method of a MRAM of claim 7, wherein before heating the magnesium layer, the magnesium layer has a first thickness, before heating the first tantalum layer, the first tantalum layer has a second thickness, and the first thickness is greater than the second thickness.

11. The fabricating method of a MRAM of claim 10, wherein the first thickness is 3 times the second thickness.

12. The fabricating method of a MRAM of claim 7, wherein the magnetic tunnel junction further comprising: a pinned layer, a reference layer and an oxide layer stacked from bottom to top, and the oxide layer contacts the free layer, and wherein the pinned layer comprises PtMn, IrMn or PtIr, the reference layer and the free layer respectively comprise Fe, Co, Ni, FeNi, FeCo, CoNi, FeB, FePt, FePd or CoFeB, the oxide layer comprises MgO, Al₂O₃, NiO, GdO, Ta₂O₅, MoO₂, TiO₂ or WO₂, the top electrode and the bottom electrode respectively comprise Ti, Ta, TiN, TaN, W, Cu or Al, the cap layer further comprises a first metal layer, a second metal layer and a third metal layer sequentially stacked from bottom to top on the magnesium layer, the magnesium oxide layer, the first tantalum layer and the tantalum oxide layer, and the first metal layer, the second metal layer and the third metal layer respectively comprise Ru, Ta, V, Mn, Zn, Mo, W, Re or Os.

13. The fabricating method of a MRAM of claim 7, wherein the magnesium layer and the first tantalum layer are deposited by physical vapor deposition.

14. A fabricating method of a magnetoresistive random access memory (MRAM), comprising:
forming a bottom electrode, a magnetic tunnel junction, a cap layer and a top electrode stacked in sequence from bottom to top, wherein the magnetic tunnel junction comprises a free layer, and fabricating steps of the cap layer comprise:
depositing a magnesium layer and a first tantalum layer in a listed sequence; and
providing oxygen gas and heating the magnesium layer and the first tantalum layer to make oxygen react with part of the magnesium layer and part of the first tantalum layer to form a magnesium oxide layer and a tantalum oxide layer.

15. The fabricating method of a MRAM of claim 14, wherein the magnesium layer, the magnesium oxide layer, the tantalum oxide layer and the first tantalum layer form a mixture layer, and the mixture layer contacts the free layer.

16. The fabricating method of a MRAM of claim 15, wherein the mixture layer comprises a bottom surface, the bottom surface contacts the free layer, the mixture layer has an oxygen atom concentration, the oxygen atom concentration increases continuously from the bottom surface toward the top electrode.

17. The fabricating method of a MRAM of claim 14, wherein before heating the magnesium layer and the first tantalum layer, the magnesium layer has a first thickness, the first tantalum layer has a second thickness, and the first thickness is greater than the second thickness.

18. The fabricating method of a MRAM of claim 17, wherein the first thickness is 3 times the second thickness.

19. The fabricating method of a MRAM of claim 14, wherein the magnetic tunnel junction further comprising: a pinned layer, a reference layer and an oxide layer stacked from bottom to top, and the oxide layer contacts the free layer, and wherein the pinned layer comprises PtMn, IrMn or PtIr, the reference layer and the free layer respectively comprise Fe, Co, Ni, FeNi, FeCo, CoNi, FeB, FePt, FePd or CoFeB, the oxide layer comprises MgO, Al₂O₃, NiO, GdO, Ta₂O₅, MoO₂, TiO₂ or WO₂, the top electrode and the bottom electrode respectively comprise Ti, Ta, TiN, TaN, W, Cu or Al, the cap layer further comprises a first metal layer, a second metal layer and a third metal layer sequentially stacked from bottom to top on the magnesium layer, the magnesium oxide layer, the first tantalum layer and the tantalum oxide layer, and the first metal layer, the second metal layer and the third metal layer respectively comprise Ru, Ta, V, Mn, Zn, Mo, W, Re or Os.

20. The fabricating method of a MRAM of claim 14, wherein the magnesium layer and the first tantalum layer are deposited by physical vapor deposition.
